(19) United States
(12) Patent Application Publication
(10) Pub. No.: US 2004/0149214 A1
(43) Pub. Date: Aug. 5, 2004

(54) Vacuum processing apparatus

(75) Inventors: Jun Hirose, Nakakoma-gun (JP); Jun Ozawa, Nakakoma-gun (JP); Tomoya Okubo, Kitakoma-gun (JP); Tatsuya Fuji, Nakakoma-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 10/763,238

(22) Filed: Jan. 26, 2004

Related U.S. Application Data
(63) Continuation of application No. 09/926,676, filed on Nov. 30, 2001, now abandoned.
Application No. 09/926,676 is a 371 of international application No. PCT/JP00/03597, filed on Jun. 2, 2000.

(30) Foreign Application Priority Data
Jun. 2, 1999 (JP) 11/155039

(51) Int. Cl. C23C 16/00

(52) U.S. Cl. 118/715; 118/720

(57) ABSTRACT

This invention is a vacuum processing apparatus comprising of a vacuum processing area (14) having a stage (16) on which a substrate to be processed (17) is mounted, and a carrier port (18) provided on a periapheral wall of a processing chamber (11) forming the vacuum processing area (14) and carrying the substrate (17) onto and off the stage (16), for generating plasma in the vacuum processing area (14) and subjecting the substrate (17) on the stage (16) to a plasma processing, wherein a shutter (20) closing the carrier port (18) to prevent the plasma from being disordered when the plasma is generated in the vacuum processing chamber is provided.

### TECHNICAL FIELD

The present invention relates to a vacuum processing apparatus for forming a film or etching for a substrate to be processed by a semiconductor manufacturing technique using plasma.

### BACKGROUND ART

There is normally known a plasma processing apparatus forming a thin film, such as a CVD (chemical vapor deposition) system, or for selective etching, such as an RIE (reactive ion etching) system, using plasma with respect to the surface of a substrate to be processed while disposing the substrate, e.g., a liquid crystal glass substrate or a semiconductor wafer, in a processing chamber which is exhausted by an exhausting system to form a vacuum.

FIG. 10 is a schematic block diagram of a conventional plasma processing apparatus.

This plasma processing apparatus 1 has a cylindrical processing chamber 2 exhausted by an exhausting system, which is not shown, and a stage 4 supported by a driving shaft 3 such as a ball screw and provided in the chamber 2. The stage 4 is made flat so that a substrate to be processed (e.g., a liquid crystal glass substrate or a semiconductor wafer) 5 can be mounted on the stage 4. In addition, a bellows 6 is provided between the lower portion of the stage 4 and the bottom of the vacuum processing chamber 2 to airtightly surround the driving shaft 3. The interior of this bellows 6 communicates with an exterior and has atmospheric pressure.

Further, a carrier port 7 freely opened and closed by a gate valve, which is not shown, is provided almost at the center of the inner peripheral wall of the processing chamber 2. The substrate held by a carrier arm, which is not shown, is carried into the processing chamber 2 through the port 7 from the outside and mounted on the stage 4 or the substrate which has been treated is carried out of the processing chamber 2 through the port 7.

Accordingly, the portion of the carrier port 7 appears concave if seen from the inner peripheral wall surface of the processing chamber 2. In this state, if plasma is generated, the uniformity of plasma density is disordered. If this processing chamber 2 is applied to, for example, a CVD apparatus, problems occur. One of these problems is that the distribution of the thickness of a film deposited on the substrate becomes uneven.

Considering the problems, the vertically movable stage 4 as stated above is provided. When the substrate is carried into and out of the processing chamber 2, the stage 4 is moved slightly downward of the carrier port 7 as indicated by a two-dot chain line in FIG. 10, and the substrate 5 is handled by the transport arm. After the substrate 5 is mounted on the stage 4, the stage 4 is raised so as to prevent the concave portion of the carrier port 7 from being applied with generated plasma.

The plasma processing apparatus having the vertically movable stage 4 stated above requires a space to vertically move the stage in the processing chamber. To do so, it is necessary to make the height dimension of the processing chamber 2 large. This disadvantageously makes the overall processing apparatus large in size.

Furthermore, clearances 8 serving as movement margins are provided between the stage 4 and the inner peripheral walls of the processing chamber 2, respectively so as to vertically move the stage 4. Due to this, if plasma is generated, plasma spreads toward the lower side of the stage 4 through these clearances 8, disadvantageously making plasma density into disorder.

To solve these problems, according to a plasma processing apparatus disclosed by, for example, Jpn. Pat. Appln. KOKAI Publication No. 63-275117, a plurality of magnetic members are disposed to surround a space ranging from a plasma withdrawal port to a substrate to be processed in a chamber and these magnetic members form magnetic lines of force in a direction perpendicular to a plasma flow to thereby control the diameter of the plasma flow.

By doing so, plasma diffusion is suppressed, plasma density is made uniform and a uniform plasma processing conducted even to a substrate to be processing having a large diameter is realized. With this technique, however, it is necessary to provide motors and driving units independently of one another for the plural magnetic members so that the magnetic members generate magnetic fields in the direction perpendicular to the plasma flow, which disadvantageously complicates the structure of the apparatus.

### DISCLOSURE OF INVENTION

It is an object of the present invention to provide a vacuum processing apparatus which can prevent plasma from spreading into a carrier port for carrying a substrate to be processed into and out of a chamber when plasma is generated, which can eliminate the disorder of plasma to ensure a uniform plasma processing, which is simple in structure and which can be made small in size.

To obtain the above object, the present invention provides a vacuum processing apparatus comprising: a vacuum processing chamber having a stage mounting a substrate to be processed thereon; and a carrier port provided on a peripheral wall of the vacuum processing chamber, and carrying the substrate onto and off the stage, for generating plasma in the vacuum processing chamber and for subjecting the substrate on the stage to a plasma processing, wherein a shutter closes the carrier port when the plasma is generated in the vacuum processing chamber to thereby prevent the plasma from being disordered.

In addition, the shutter is a cylindrical member along an inner peripheral wall of the vacuum processing chamber, and is raised by a shutter driving mechanism to close the carrier port when the plasma is generated in the vacuum processing chamber. The shutter is a plate member along an inner peripheral wall of the vacuum processing chamber, and is raised by a shutter driving mechanism to close the carrier port when the plasma is generated in the vacuum processing chamber.

Further, the shutter driving mechanism is constituted out of an air cylinder disposed on an atmospheric side, and a driving shaft elevated by the air cylinder to elevate the shutter.

The vacuum processing apparatus constituted as stated above allows the shutter to be raised by an air cylinder and the carrier port for carrying the substrate into and out of the vacuum processing chamber to be closed by the shutter to eliminate uneven portions on the inner peripheral wall of the vacuum processing chamber when the plasma is generated, thereby making it possible to eliminate the disorder of the plasma and to ensure a uniform plasma processing.

### BRIEF DESCRIPTION OF DRAWINGS

FIG. 1 is a view showing the longitudinal sectional structure of a vacuum processing apparatus in a first embodiment for carrying out the present invention.

FIG. 2 is a front view of a shutter drive unit in the first embodiment for carrying out the present invention.

FIG. 3 is a perspective view of a shutter in the first embodiment for carrying out the present invention.

FIG. 4 is a view showing the cross-sectional structure of a processing chamber showing a second embodiment for carrying out the invention.

FIG. 5 is a perspective view of a shutter drive unit in the second embodiment for carrying out the invention.

FIG. 6 is a view showing the longitudinal sectional structure of a vacuum processing apparatus in a third embodiment for carrying out the invention.

FIG. 7 is a perspective view of a shutter drive unit in the third embodiment for carrying out the invention.

FIGS. 8A and 8B are views showing the cross-sectional structure of the shutter drive unit in the third embodiment for carrying out the invention.

FIG. 9 is a view showing the cross-sectional structure of a shutter drive unit in a modified example of the third embodiment for carrying out the invention.

FIG. 10 is a view showing the longitudinal sectional structure of a conventional vacuum processing apparatus.

### BEST MODE FOR CARRYING OUT OF THE INVENTION

Embodiments for carrying out the present invention will be described hereinafter in detail.

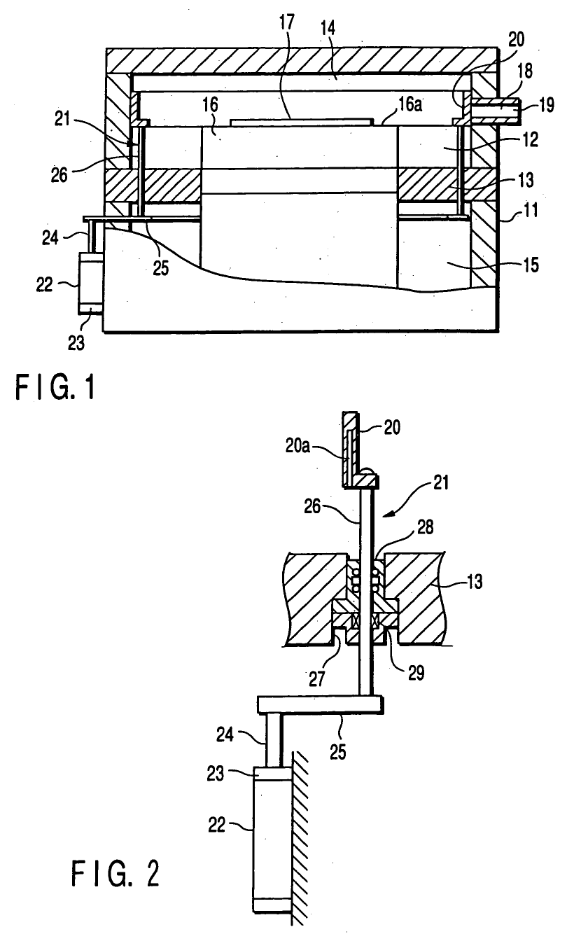

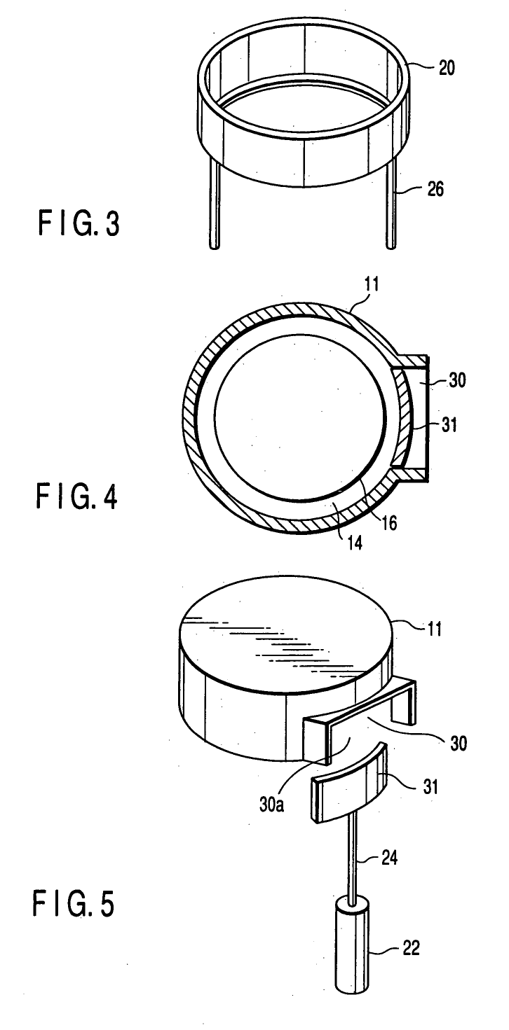

FIGS. 1 through 3 show a first embodiment for carrying out the invention. FIG. 1 is a longitudinal front view of a vacuum processing apparatus, FIG. 2 is a front view of a shutter drive unit and FIG. 3 is a perspective view of a shutter.

As shown in FIG. 1, a processing chamber 11 constituting the main body of a vacuum processing apparatus is formed out of a conductive material such as, for example, aluminum. The interior of the processing chamber 11 is vertically partitioned by a ring-shaped partition wall 13 into an upper portion used as a vacuum processing area 14 and a lower portion used as an atmospheric area 15.

A stage 16 is provided at the center of this partition wall 13. An insulating member made of quartz or the like is arranged on the upper surface of this stage 16 to provide a mounting surface 16a on which a substrate to be processed 17, such as a liquid crystal glass substrate or a semiconductor wafer, is mounted.

The surface of the stage 16 is made of aluminum or the like and subjected to, for example, an alumite treatment (anode oxide coating). A heating region such as a ceramic heater, a temperature control mechanism such as a coolant channel and a temperature sensor (these elements are not shown) are provided inside the stage 16.

A carrier port 18 for carrying the substrate 17 onto and out of the mounting surface 16a by a carrier arm (not shown) is provided on a part of the peripheral wall of the processing chamber 11 constituting a vacuum processing area 14. This carrier port 18 has a flat rectangular shape along the peripheral direction of the processing chamber 11 and has a protrusion port 19 formed integrally with the carrier port 18 and protruding from the opening edge to the outside.

Further, a shutter 20 is provided along the inner peripheral wall of the processing chamber 11 to be freely elevated. As shown in FIGS. 2 and 3, this shutter 20 is made of the same conductive material as that of the processing chamber 11 such as aluminum and is a cylindrical body having an opening at both ends. The shutter 20 is formed such that the height of the peripheral wall is large enough to close the carrier port 18. The shutter 20 is vertically moved by a shutter drive mechanism 21 to be described later.

Further, an electric heater 20a is built in the shutter 20. The heater 20a has functions of preventing heat loss, improving processing efficiency, suppressing the adhesion of a reactive product and lengthening a maintenance cycle. The potential of the shutter 20 is grounded.

Next, the shutter driving mechanism 21 will be described.

An air cylinder 22 is attached to the atmospheric area 15 on the lower portion of the processing chamber 11 by an attachment tool 23 in a vertical direction. A ring-shaped elevation plate 25 is horizontally fixed to the elevation rod 24 of the air cylinder 22.

A plurality of driving shafts 26 are provided on the elevation plate 25 in the vertical direction of the plate 25. The shutter 20 is fixed to the upper ends of these driving shafts 26 by screws. The driving shafts 26 are axially, slidably provided in guide holes 27 penetrating the partition wall 13, and a seal member 28 and a slide bearing 29 are provided in each guide hole 27.

By elevating the elevation rod 24 by the air cylinder 22, the shutter 20 is elevated through the elevation plate 25 and the driving shafts 26. The carrier port 18 is opened by the shutter 20 at a shutter descending position and closed by the shutter 20 at a shutter rising position, and an even, flat surface is formed on the peripheral wall of the vacuum processing area 14. The shutter 20 also functions as a deposit shield.

Next, the function of the first embodiment for carrying out the invention will be described.

First, the elevation rod 24 is descended by the air cylinder 22, and the shutter 20 is descended and retreated through the elevation plate 25 and the driving shafts 26. Then, the carrier port 18 is opened. In this state, the substrate to be processed 17 held by the carrier arm is carried through the carrier port 18 into the vacuum processing area 14 and mounted on the mounting surface 16a of the stage 16.

Next, the carrier port 18 is closed by a gate valve (not shown) and the vacuum processing area 14 is exhausted to form a vacuum. It is noted that the vacuum processing area 14 may be evacuated in advance. After the vacuum processing area 14 has a predetermined degree of vacuum, process gas is introduced into the vacuum processing area 14. At the same time, the air cylinder 22 is driven to raise the elevation rode 24. Then, the shutter 20 is raised through the elevation plate 25 and the driving shafts 26 to close the carrier port 18. As a result, an even, flat surface is formed on the peripheral wall of the vacuum processing area 14.

Next, plasma is generated in the vacuum processing area 14 to subject the substrate 17 to a plasma processing. At this moment, the shutter 20 cylindrically surrounds a plasma generation region. Since this shutter 20 has no uneven portions, a plasma flow has no deviation and the uniformity of the plasma processing is ensured even for the substrate 17 having a large diameter. For example, if a film is formed on the substrate 17 by plasma CVD, a uniform film thickness can be obtained.

Furthermore, it is not necessary to elevate the stage 16 but it suffices to elevate only the shutter 20 in the vacuum processing area 14. This makes it possible to decrease the height dimension of the vacuum processing area 14, to make the apparatus small in size, to save energy and to reduce cost.

Next, a vacuum processing apparatus according to the second embodiment for carrying out the present invention will be described.

FIG. 4 is a cross-sectional plan view of a processing chamber 11 constituting a vacuum processing area 14 and FIG. 5 is a perspective view of a shutter drive unit. In this embodiment for carrying out the invention, the same constituent elements as those in the first embodiment for carrying out the invention described above are denoted by the same reference symbols and no detailed description will be given thereto.

A carrier port 30 is provided on a part of the peripheral wall of the processing chamber 11 of this vacuum processing apparatus and opened to have a flat rectangular shape along the peripheral direction of the processing chamber 11. The carrier port 30 has also an opening portion 30a on a lower end thereof.

Further, a gate 31 airtight opening and closing the carrier port 30 is provided in the vacuum processing area 14 to be freely elevated. This gate 31 is made of the same conductive material, such as aluminum, as that of the processing chamber 11, formed into a rectangular plate shape having such a dimension as to close the opening portion of the carrier port 30, and curved to have the same curvature as that of the peripheral wall of the processing chamber 11.

This gate 31 is coupled to the elevation rod 24 of an air cylinder 22 provided on an atmospheric area 15 side on the lower portion of the processing chamber 11 so as to be elevated. At the descending position of the elevation rode 24, the gate 31 is descended to open the carrier port 30. At the rising position thereof, the gate 31 airtight closes the carrier port 30. As a result, no uneven portions appear on the peripheral wall of the vacuum processing area 14.

According to this embodiment for carrying out the present invention, it suffices that only the gate 31 opening and closing the carrier port 30 is driven to be elevated. As in the case of the above-stated shutter, it is possible to eliminate uneven portions on the peripheral surface of the vacuum processing area 14, to form the gate 31 to be small in size and light in weight, and to make the air cylinder 22 small in size.

Next, a vacuum processing apparatus in a third embodiment for carrying out the present invention will be described.

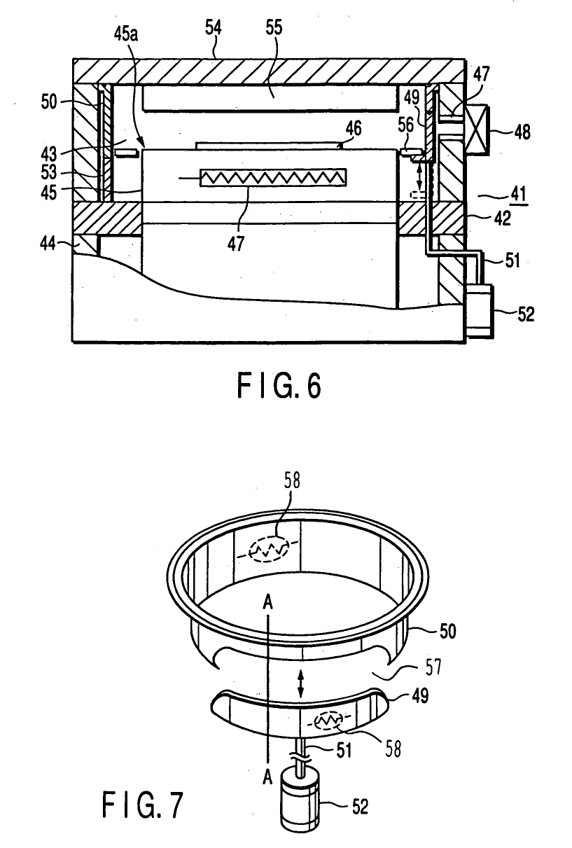

FIG. 6 is a longitudinal sectional front view of a vacuum processing apparatus in this embodiment for carrying out the present invention.

A processing chamber 41 constituting the main body of this vacuum processing apparatus is formed out of a conductive material such as aluminum. The interior of the processing chamber 41 is vertically partitioned by a ring-shaped partition wall 42 into an upper portion used as a vacuum processing area 43 and a lower portion used as an atmospheric area 44.

A stage 45 is provided at the center of this partition wall 42. An insulating member made of quartz or the like is arranged on the upper surface of this stage 45 to provide a mounting surface 45a on which a substrate to be processed 46, such as a liquid crystal glass substrate or a semiconductor substrate, is mounted. Also, a disk-shaped evacuation plate 56 is provided around the stage 45. The surface of the stage 45 is made of aluminum or the like subjected to, for example, an alumite treatment (anode oxide coating). A heating region 47 such as a ceramic heater, a temperature control mechanism such as a coolant channel and a temperature sensor (not shown) are provided inside the stage 45.

A carrier port 47 for carrying the substance 46 onto and out of the mounting surface 45a by a carrier arm (not shown) is provided on a part of the inner peripheral wall of the vacuum processing area 43. A gate valve 48 opening and closing the carrier port 47 is provided on the atmospheric side of the carrier port 47. This gate valve 48 is driven by an air cylinder or the like, which is not shown. If the gate valve 48 is closed, the interior of the vacuum processing area 43 is maintained airtight.

In addition, an upper electrode 55 including a gas introduction system is provided in the ceiling plate 54 of the processing chamber 41. Further, a freely elevated shutter 49 and a fixed deposit shield 50 are provided in the vacuum processing area 43 as shown in FIG. 7.

This deposit shield 50 is made of a conductive material such as aluminum, formed into a cylindrical shape having both ends opened and, as shown in FIG. 6, fixed through a spacer 53 in the vacuum processing area 43. The deposit shield 50 is grounded to have a GND potential equal to the potential of the processing chamber. The deposit shield 50 also has a partial notch portion into which portion the raised shutter 49 is fitted.

Further, an electric heater (not shown) is built in each of the shutter 49 and the deposit shield 50 to so as to function to prevent heat loss in the vacuum processing area 43, to improve treatment efficiency, to suppress the adhesion of a reactive product and to lengthen a maintenance cycle.

This shutter 49 is coupled to one end of a driving shaft 51 airtightly introduced from the atmospheric area 44 on the lower portion of the processing chamber 41 using a magnetic fluid seal or the like. The other end of this driving shaft 51 is coupled to an air cylinder 52. The air cylinder 52 drives the shutter 49 to be vertically elevated. Namely, if the substrate is carried into and out of the processing chamber through the carrier port 47, the shutter 49 is descended to be retreated. When plasma is generated, the shutter 49 is raised to be fitted into the notch portion of the deposit shield 50 to thereby form an even curve.

In a second embodiment for carrying out the invention stated above, to eliminate the height difference between the raised shutter 31 and the peripheral wall of the processing chamber 11 and to form the same peripheral surface, the shutter 31 is preferably made close to the processing chamber 11 as much as possible. However, if the shutter 31 is raised and abutted on the processing chamber 11, the abutted portions are worn and particles may possibly be generated. If clearances are formed to prevent the abutted portions from being worn, however, the shutter is electrically disconnected from the processing chamber 11. Then, the shutter is exposed to plasma in the processing apparatus using plasma and, therefore, the shutter has sometimes a different potential from that of the processing chamber 11.

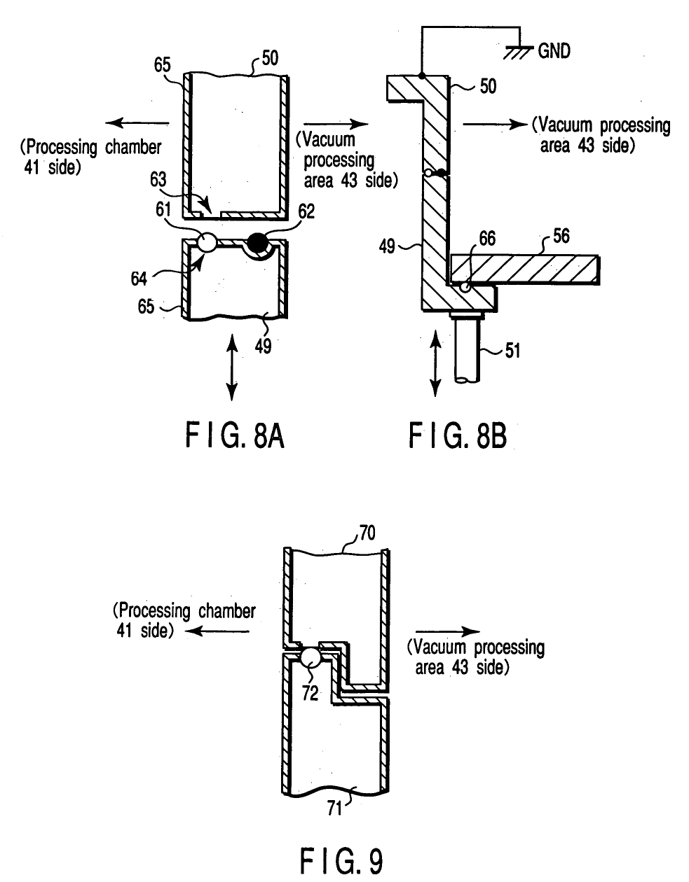

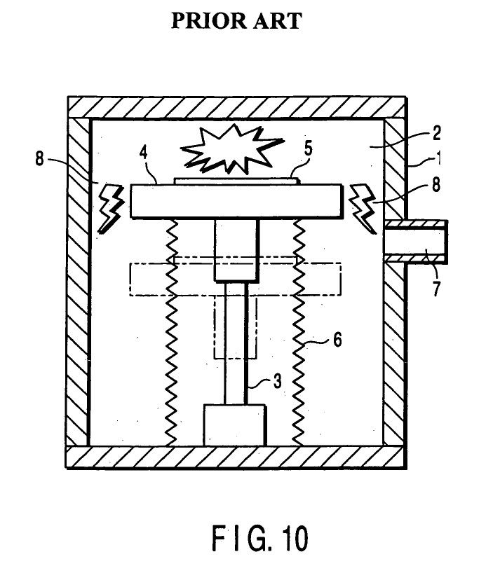

To prevent this, as shown in FIG. 8A which is a cross-sectional view taken along A-A of FIG. 7, a spiral seal 61 made of metal such as stainless is used to electrically connect the deposit shield 50 to the shutter 49. That is, a groove containing the spiral seal 61 so that a part of the seal 61 is protruded from the groove is formed on the end face of the shutter 49 and a groove containing an O ring is also formed in parallel to the former groove. At this moment, the spiral seal groove is formed on the processing chamber 41 side whereas the O ring groove is formed on the vacuum area side. In addition, alumite 65 on the inner surface 64 of the spiral seal groove and the contact surface 63 of the deposit shield 50, on which the spiral seal 61 is abutted, is removed to allow electrical connection.

As shown in FIG. 8B, if the shutter 49 raised by the driving shaft 51 is abutted on the deposit shield 50 and the spiral seal 61 contacts with the contact surface 63 of the deposit shield 50, metallic powder, i.e., particles may possibly be generated. Even so, the O ring 62 can prevent the particles from entering the vacuum processing area 43 side. The O ring also functions to absorb an impact generated when the shutter 49 is abutted on the deposit shield 50.

Alternatively, a spiral seal 66 may be provided so that the shutter 49 can be contacted with and electrically connected to the evacuation plate 56 when the shutter 49 is raised in the same manner.

Next, a modified example of the third embodiment for carrying out the present invention will be described with reference to FIG. 9.

In this modified example, the end faces of the shutter 49 and the deposit shield 50 abutted on each other have different shapes from those in the third embodiment and the abutment of the shutter on the deposit shield is realized without using an O ring.

As shown in FIG. 9, the end faces of the shutter and the deposit shield are L-shaped to engage them with each other. At this moment, the processing chamber 41 side is made higher than the vacuum processing area 43 side, i.e., the outer peripheral side is made convex.

In this modified example as in the case of the third embodiment, the same spiral seal groove as that described above is formed on the convex end face of the shutter 49 and a spiral seal 72 is fitted into the groove, If the shutter 71 is raised, the shutter 71 is abutted on the deposit shield 70 to establish electrical connection therebetween. In this case, because of the L-shaped abutted portions, even if particles are generated at the time of the contact of the spiral seal 72 with the deposit shield 70, the particles are shielded by the L-shaped portions to thereby prevent the particles from reaching the substrate 46. As a result, an even, flat surface is formed on the peripheral wall of the vacuum processing area side. While the O ring is used in the third embodiment for carrying out the invention, a groove can be formed into such a shape, e.g., U-shape, as to generate an elastic force using Teflon or the like.

As stated so far, according to the present invention, the carrier port for carrying the substrate into and out of the vacuum processing chamber is closed by the shutter to thereby eliminate uneven portions on the inner peripheral wall of the vacuum processing area side. By doing so, when plasma is generated, plasma disturbance can be eliminated to advantageously ensure a uniform plasma processing. Furthermore, since it is not necessary to elevate the mounting base on which the substrate is mounted, it is possible to advantageously simplify the structure of the apparatus and to advantageously make the apparatus small in size.

Moreover, since the deposit shield, the shutter and the evacuation plate have an equal electrical potential (e.g., ground potential), it is possible to eliminate the electrical plasma disturbance and to further ensure a uniform plasma processing.

### INDUSTRIAL APPLICABILITY

The present invention is intended to provide a vacuum processing apparatus capable of eliminating plasma disturbance and conducting a uniform plasma processing when the plasma is generated by removing uneven portions from the inner peripheral wall of the vacuum processing area side of the present invention.

The vacuum processing apparatus of the present invention is provided with a vacuum processing chamber in which a predetermined processing is conducted to a substrate to be processed mounted on a stage using plasma, and a shutter covering the inner peripheral wall of the vacuum processing area and vertically moved. This shutter is entirely retreated when the substrate is carried onto and out of the stage through a carrier port, and disposed to surround a plasma generation region when a plasma processing is conducted, so that the shutter eliminates uneven portions in the vacuum processing area and functions as a deposit shield. Also, a deposit shield is fixed to cover the inner peripheral wall of the vacuum processing area on the outer periphery of the stage, a notch portion to cover the carrier port is provided, and a freely elevated shutter fitted into this notch portion is provided. The shutter is descended to be retreated when the substrate is carried into and out of the processing chamber through the carrier port, and raised to be fitted into the notch portion when a plasma processing is conducted, thereby forming a curve without uneven portions, having an equal potential, eliminating plasma disturbance and ensuring a uniform plasma processing.

1. A vacuum processing apparatus for generating a plasma including a vacuum processing chamber having a stage for mounting a substrate to be processed, and a carrier port for carrying the substrate onto and off the stage for subjecting the substrate on the stage to a plasma processing in the vacuum processing chamber, said apparatus, comprising:
a deposit shield disposed along an inner peripheral wall of the vacuum processing chamber, and having a notch portion at a position facing the carrier port;
a shutter having a shape fitted into the notch portion of the deposit shield, having a same inside curvature as an even curvature of an inner surface of the deposit shield when the shutter is fitted into the notch portion, and being configured to be elevated;
a sealing groove being configured to receive an O-ring therein, said sealing groove being formed in an end face of the shutter opposing a flat side face of the deposit shield; and
a conduction groove being configured to receive therein a spiral seal made of metal, said conduction groove formed in the end face of the shutter parallel to and outside of the sealing groove, the spiral seal electrically connecting the deposit shield to the shutter,
wherein each of the deposit shield and the shutter is configured to have a ground potential, the shutter is configured to be retreated from the notch portion when moving the substrate in and out of the stage through the carrier port and configured to be fitted into the notch portion of the deposit shield when the plasma processing is conducted, thus surrounding a plasma generation region by the even curvature of the shutter and deposit shield thereby producing a uniform plasma.

2. A vacuum processing apparatus for generating a plasma including a vacuum processing chamber having a stage for mounting a substrate to be processed, and a carrier port for carrying the substrate onto and off the stage for subjecting the substrate on the stage to a plasma processing in the vacuum processing chamber, said apparatus, comprising:
a deposit shield disposed along an inner peripheral wall of the vacuum processing chamber, and having a notch portion at a position facing the carrier port;
a shutter having a shape fitted into the notch portion of the deposit shield, having a same inside curvature as an even curvature of an inner surface of the deposit shield when the shutter is fitted into the notch portion, and being configured to be elevated;
a sealing groove being configured to receive an O-ring therein, said sealing groove being formed in an end face of the shutter opposing a flat side face of the deposit shield; and
a conduction groove being configured to receive therein a spiral seal made of metal, said conduction groove formed in the end face of the shutter parallel to and outside of the sealing groove, the spiral seal electrically connecting the deposit shield to the shutter,
wherein when the plasma is generated in the vacuum processing chamber, the shutter is raised by a shutter mechanism to be fitted into the notch portion thereby closing the carrier port and forming the same inner surface curvature as the even curvature of the inner surface of the deposit shield, and
wherein further each of the deposit shield and the shutter is configured to have a ground potential, the shutter is configured to be retreated from the notch portion when moving the substrate in and out of the stage through the carrier port and configured to be fitted into the notch portion of the deposit shield when the plasma processing is conducted, thus surrounding a plasma generation region by the even curvature of the shutter and deposit shield thereby producing a uniform plasma.

3. A vacuum processing apparatus for generating a plasma, including a vacuum processing chamber having a stage for mounting a substrate to be processed, and a carrier port provided on a peripheral wall of the vacuum processing chamber for carrying the substrate onto and off the stage for subjecting the substrate on the stage to a plasma processing in the vacuum processing chamber, said apparatus, comprising:
a deposit shield disposed along an inner peripheral wall of the vacuum processing chamber, and having a notch portion with a flat end face;
a shutter having a shape fitted into the notch portion of the deposit shield, having a same inside curvature as an even curvature of an inner surface of the deposit shield when the shutter is fitted into the notch portion, and being configured to be elevated;
a sealing groove being configured to receive an O-ring therein, said sealing groove being formed in an end face of the shutter opposing a flat side face of the deposit shield; and
a conduction groove being configured to receive therein a spiral seal made of metal, said conduction groove formed in the end face of the shutter parallel to and outside of the sealing groove, the spiral seal electrically connecting the deposit shield to the shutter.

4. The vacuum processing apparatus according to claim 3, wherein a disk-shaped evacuation plate is disposed around the stage, and the shutter and the evacuation plate are brought into contact with each other and electrically connected to each other when the shutter is raised.

5. The vacuum processing apparatus according to claim 3, wherein each of the deposit shield and the shutter comprises a heating mechanism.

6. A vacuum processing apparatus for generating a plasma, including a vacuum processing chamber having a stage for mounting a substrate to be processed, and a carrier port provided on a peripheral wall of the vacuum processing chamber for carrying the substrate onto and off the stage for subjecting the substrate on the stage to a plasma processing in the vacuum processing chamber, said apparatus, comprising:
a deposit shield disposed along an inner peripheral wall of the vacuum processing chamber, and having a notch portion at a position facing the carrier port, the notch having an end face having an L-shape cross section, the end face of the L-shape cross section having a convex outer periphery;
a shutter having a shape fitted into the notch portion of the deposit shield, having a same inside curvature as an even curvature of an inner surface of the deposit shield when the shutter is fitted into the notch portion, and being configured to be elevated;
a sealing groove being configured to receive an O-ring therein, said sealing groove being formed in an end face of the shutter opposing a flat side face of the deposit shield; and
a conduction groove being configured to receive therein a spiral seal made of metal, said conduction groove formed in the end face of the shutter parallel to and outside of the sealing groove, the spiral seal electrically connecting the deposit shield to the shutter.

7. The vacuum processing apparatus according to claim 6, wherein a disk-shaped evacuation plate is disposed around the stage, and the shutter and the evacuation plate are brought into contact with each other and electrically connected to each other when the shutter is raised.

8. The vacuum processing apparatus according to claim 6, wherein each of the deposit shield and the shutter comprises a heating mechanism.

9. A vacuum processing apparatus for generating a plasma, including a vacuum processing chamber having a stage for mounting a substrate to be processed, and a carrier port provided on a peripheral wall of the vacuum processing chamber for carrying the substrate onto and off the stage for subjecting the substrate on the stage to a plasma processing in the vacuum processing chamber, said apparatus, comprising:
a deposit shield disposed along an inner peripheral wall of the vacuum processing chamber, said deposit shield having a first heating mechanism; and
a shutter configured to be elevated along the inner peripheral wall of the vacuum processing chamber, said shutter having a second heating mechanism,
wherein each of the deposit shield and the shutter is configured to have a grounded potential, the shutter is configured to be retreated when the substrate is moved in and out of the stage through the carrier port and configured to be abutted on the deposit shield when the plasma processing is conducted, thus surrounding a plasma generation region by an even curvature of the shutter and deposit shield thereby generating a uniform plasma.

10. The vacuum processing apparatus according to claim 9, wherein a disk-shaped evacuation plate is disposed around the stage, and the shutter and the evacuation plate are brought into contact with each other and electrically connected to each other when the shutter is raised.
